(19) United States
(12) Patent Application Publication
(10) Pub. No.: US 2009/0068358 A1
(43) Pub. Date: Mar. 12, 2009

(54) PLASTIC CODE WHEEL/STRIP FABRICATION METHOD

(76) Inventor: Yun-Long Lai, Taipei (TW)

Correspondence Address: PAI PATENT & TRADEMARK LAW FIRM, 1001 FOURTH AVENUE, SUITE 3200, SEATTLE, WA, 98154, US

(21) Appl. No.: 12/051,858

(22) Filed: Mar. 20, 2008

(30) Foreign Application Priority Data
Sep. 7, 2007 (TW) 096133349

(51) Int. Cl. C23C 16/04

(52) U.S. Cl. 427/250; 430/5; 264/293

(57) ABSTRACT

A method of making a plastic code wheel/code strip by: depositing a chrome-aluminum film on a plastic substrate having a transmittance greater than 90%, a transmittance greater than 90%, a heat resistance to at least 120° C. and a thickness smaller than 0.5 mm; forming a photoresist layer on the chrome-aluminum film; covering a patterned film strip on the photoresist layer; radiating the patterned film strip with a collimated light source to expose the optical grating pattern into the photoresist layer; removing the patterned film strip and the non-exposed photoresist from the chrome-aluminum film; etching the chrome-aluminum film; removing the photoimaged photoresist so as to obtain a semi-finished product having an optical grating pattern; and then stamping the semi-finished product into a finished product according to a predetermined shape.

### BACKGROUND OF THE INVENTION

(a) Field of the Invention

The present invention relates to the fabrication of code wheels/code strips and more particularly to a plastic code wheel/strip fabrication method which utilizes a plastic material such as polyethylene terephthalate or polycarbonate for the substrate for making a code wheel or code strip with an optical grating pattern suitable for use in an optical encoder or optical scale.

(b) Description of the Prior Art

A code wheel is an element used in an encoder for industrial measurement application. A code strip (graduated scale) is an element for use in a narrow elongated optical scale. A code wheel or code strip (graduated scale) has a pattern of optical gratings for encoding. The optical encoder focuses light on the code wheel or code strip. As the code wheel or code strip moves with respect to the optical encoder, an optical sensor reads a pattern of light transmitted through the code wheel or code strip to detect the motion.

With the development of nanometer technology, high precision and high heat resistance are the requisite features for component parts. Originally, a code wheel utilizes a glass substrate. During fabrication of a glass code wheel, a glass substrate is coated with a thin layer of chrome-aluminum film by means of vapor deposition, and then a photoresist is covered on the chrome-aluminum film, and then a patterned film strip is covered on the photoresist. After an exposure process, the non-exposed photoresist is removed, and the workpiece is etched with an acid or alkaline etching solution. After etching, the photoimaged photoresist is removed, thus finishing the optical grating pattern engraving. After engraving of the optical grating pattern, the glass is processed through complicated grinding procedure so that the optical grating pattern is concentric with respect to the periphery of the glass, and then a round hole is formed on the center. This code wheel fabrication is complicated, wasting much time and labor, and the glass may be broken accidentally during processing. Due to the limitations of the glass material, it is difficult to eliminate the aforesaid problems. Further, the formation of the center hole is done by means of a grinding process. It cannot be formed by means of diamond cutting. This center hole grinding process takes much time, thus lowering the productivity. Conventionally, the fabrication of a code strip (graduated scale) uses a glass substrate. Except for the narrow elongated shape, the fabrication of a glass code strip is substantially similar to the fabrication of a glass code wheel.

Further, a code wheel is a key component part in an encoder. It is shaped like a mini compact disc, having a center through hole for the mounting of the encoder shaft. The code wheel has a plurality of equal-sized opaque lines (like barcodes) equiangularly spaced around the center through hole. The encode wheel is set between a light source and an optical sensor and rotated to produce “0” and “1” signals. These signals are used to determine the rotation frequency and direction of rotation of the code wheel. Assume a code wheel produces 360 pulse signals when rotated through 360°, a number will be indicated on the scale indicative of the number of degrees of rotation of the code shaft. If the code wheel is fastened to a screw rod that has a pitch (tooth pitch) 3.60 mm, the angle of rotation of the code wheel is indicative of the moving distance of the worktable. Therefore, the number of opaque lines of the code wheel is determined according to the application. The size of the code wheel is also determined according to the load to be taken by the encoder. Because a glass substrate for glass code wheel is fragile, the technique for making the center through hole is complicated and difficult. Normally, a grinding wheel is used to grind the glass substrate slowly. During grinding, the operator must watch out for the concentricity.

There is known a code wheel fabrication method using a metal substrate. According to this code wheel fabrication method, a photoresist is coated on a metal substrate, and then a patterned film strip is placed on the photoresist to undergo an exposure process. After the exposure process, the non-exposed photoresist is removed, and then an etching process is employed. After etching, the photoimaged photoresist is removed, the optical grating pattern engraving is finished, and thus a code wheel is obtained. This method eliminates the complicated grinding procedure as employed during the fabrication of a glass code wheel. However, in order to let light pass, the metal substrate has a thin thickness. Because of thin thickness, the code wheel has low strength. During rotation with the encoder shaft, the code wheel may vibrate. Therefore, a metal code wheel can only be used in a low resolution product, not suitable for use in a high resolution product.

There is known a code wheel using a film substrate. During fabrication of this kind of code wheel, a film (photographic film) is prepared and processed through a series of processes including laser radiation, image developing, image setting, solution washing and drying. However, a code wheel of this design has a low temperature resistance below 50° C. Further, it is soft. Therefore, this kind of code wheel can only be used in a regular office machine, not suitable for industrial application under a high temperature environment. Although a film code wheel is cheap. The desired optical grating pattern can be directly formed on the prepared film substrate by means of a laser plotter. After image developing, image setting and solution washing, the substrate is directly punched with a punch die, and the desired film code wheel is finished. Besides the drawback of low heat resistance, there is no thickness option, i.e., the fabrication of a film code wheel is limited to the film thickness specifications provided by the film provider.

Therefore, it is desirable to provide a code wheel/strip fabrication method that is practical for making code wheels/code strips that eliminate the aforesaid problems.

### SUMMARY OF THE INVENTION

The present invention has been accomplished under the circumstances in view. It is the main object of the present invention to provide a plastic code wheel/strip fabrication method, which utilizes a plastic substrate for making a code wheel/strip that has a heat resistance to 120° C., excellent transmittance, high strength. A code wheel/strip is practical for use in an optical encoder or optical scale, and has an industrial value.

It is another object of the present invention to provide a plastic code wheel/strip fabrication method, which utilizes a plastic substrate for making a code wheel/strip. The plastic substrate can be prepared from polyethylene terephthalate or polycarbonate for the advantage of high thickness control lability. The finished product thus made has excellent light blocking effect. During fabrication, it is not necessary to apply a complicated grinding process to the semi-finished product. The finished product shows high precision stability, and has an industrial value.

It is still another object of the present invention to provide a plastic code wheel/strip fabrication method, which is practical for making a plastic code wheel/strip having high strength. A plastic code wheel made according to the present invention does not vibrate when rotated, therefore it is suitable for use in a high-resolution encoder.

### BRIEF DESCRIPTION OF THE DRAWINGS

FIG. 1 is a schematic drawing illustrating a code wheel/strip fabrication process according to the present invention.

FIG. 2 is a schematic plan view of a code wheel made according to the present invention.

FIG. 3 is a schematic plan view of a code strip (graduated scale) made according to the present invention.

### DETAILED DESCRIPTION OF THE PREFERRED EMBODIMENTS

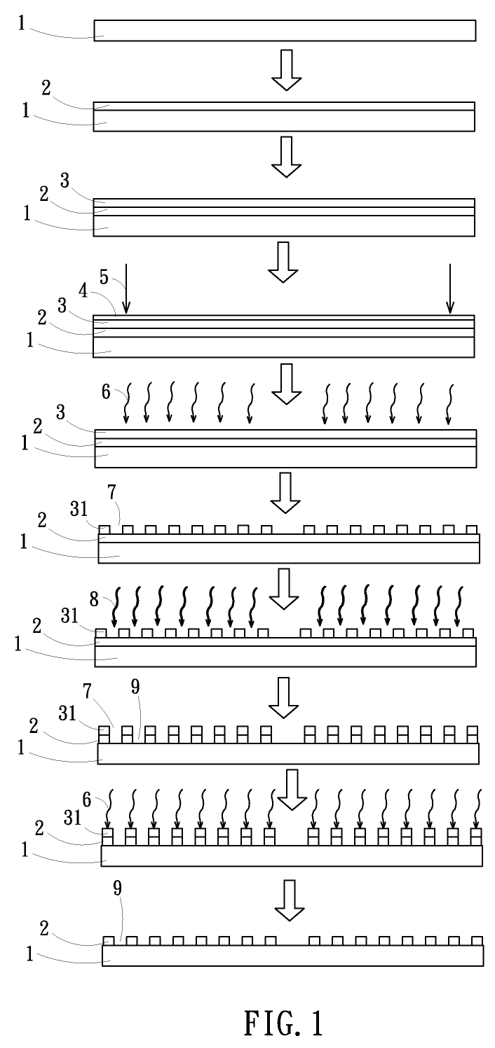

Referring to FIGS. 1˜3, a plastic code wheel/strip fabrication method in accordance with the present invention is adapted for making plastic code wheels or code strips. A plastic code wheel made according to the present invention can be used in an optical encoder. A plastic code strip made according to the present invention is a graduated scale practical for use in an optical scale. A plastic code wheel/strip comprises a plastic substrate 1 that has a transmittance greater than 90%, a heat resistance to 120° C., and a thickness smaller than 0.5 mm. Preferably, the plastic substrate 1 is prepared from PET (polyethylene terephthalate) or PC (polycarbonate) for the advantages of excellent heat resistance and hardness and ease of processing. After the plastic substrate 1 is prepared, a chrome-aluminum film 2 is deposited on the surface of the plastic substrate 1 by means of vapor deposition, and then a photoresist is sprayed on the surface of the chrome-aluminum film 2 to form a photoresist layer 3 having a thickness about 1˜3 μm. After the photoresist layer 3 is dried through a drying process, a patterned film strip 4 that carries an optical grating pattern that was drawn by means of a photoplotter is placed on the photoresist layer 3, and then a collimated light source 5 is applied to the patterned film strip 4, exposing the optical grating pattern of the patterned film strip 4 into the photoresist layer 3. After the radiation of the collimated light source 5, the patterned film strip 4 is removed from the photoresist layer 3, and then the workpiece is dried through a drying process. Thereafter, a cleaning solution 6 is applied to remove the non-exposed photoresist 7, and then a drying process is employed to dry the workpiece. Thereafter, an etching solution 8 is applied to dip-etch the plastic substrate 1 and the chrome-aluminum film 2 within one minute. After etching, a cleaning solution 6 is applied again to remove the photoimaged photoresist 31, and then a drying process is employed to dry the workpiece (semi-finished product) that has an optical grating pattern 9. The workpiece (semi-finished product) is then put in an optical press and then stamped, forming the desired code wheel or code strip (graduated scale). The aforesaid cleaning solution 6 is preferably an alkaline solution. The etching solution 8 can be a nitride acid solution (such as CAN/HNO3). Further, the drying process can be air drying or baking.

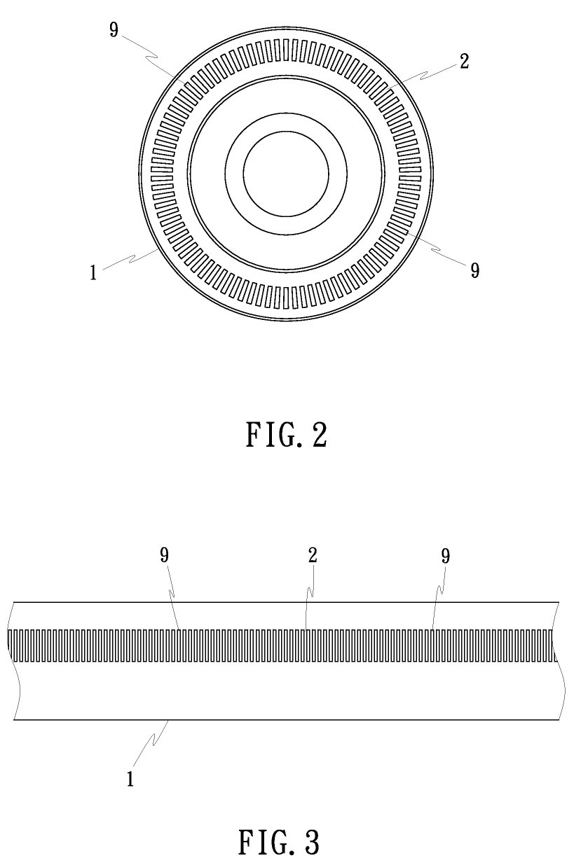

FIG. 2 illustrates a plastic code wheel made according to the present invention. In a code wheel of diameter within 25 mm, there are 360˜720 gratings. FIG. 3 illustrates a plastic code strip made according to the present invention. The plastic code strip is a narrow elongated strip having an optical grating pattern.

When compared with a glass code wheel, a plastic code wheel made according to the present invention has the advantages of: low cost, ease in fabrication, high precision controllability, less fragility, high flexibility, light weight, heat resistance to 120° C., ease of installation and thin thickness.

When compared with a metal code wheel, a plastic code wheel has the advantages of: low cost, high precision, low deformability and high durability.

| | | | Plastic |
|---|---|---|---|
| | | | code wheel |
| | Glass code wheel | Metal code wheel | (the invention) |
| Coating | Required | Not required | Required |
| Patterned | Patterned glass-strip | Patterned film | Patterned film |
| strip | (expensive) | strip (cheap) | strip (cheap) |
| Shape-form | Complicated tooling | Simple (cheap) | Medium (regular) |
| | (cheap) | | |
| Precision | High | Low | High |
| Heat | 100° C. | 100° C. | 120° C. |
| resistant | | | |
| Drawback | Fragile | Easy to injure | No |
| Cost | High | Low | Low |

In conclusion, the invention utilizes a plastic substrate 1 for making a code wheel or code strip that shows high precision stability when used under a high temperature environment. Therefore, a code wheel or code strip made according to the present invention has excellent usability.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A plastic code wheel/code strip fabrication method comprising the steps of:
a) preparing a plastic substrate having a transmittance greater than 90%;
b) depositing a chrome-aluminum film on a surface of said plastic substrate by means of vapor deposition;
c) forming a photoresist layer on said chrome-aluminum film;
d) preparing a patterned film strip carrying an optical grating pattern and placing said patterned film strip on said photoresist layer;
e) applying a collimated light source to said patterned film strip, exposing the optical grating pattern of said patterned film strip into said photoresist layer;
f) removing said patterned film strip from said photoresist layer;
g) removing non-exposed portion of the photoresist layer from said chrome-aluminum film with a cleaning solution to leave a photoimaged photoresist on the chrome-aluminum film;
h) dip-etching said chrome-aluminum film with an etching solution;
i) removing the photoimaged photoresist with a cleaning solution so as to obtain a semi-finished product having an optical grating pattern; and
j) stamping said semi-finished product into a finished product according to a predetermined shape.

2. The plastic code wheel/code strip fabrication method as claimed in claim 1, wherein said plastic substrate is prepared from polyethylene terephthalate that has a heat resistance to at least 120° C.

3. The plastic code wheel/code strip fabrication method as claimed in claim 1, wherein said plastic substrate is prepared from polycarbonate that has a heat resistance to at least 120° C.

4. The plastic code wheel/code strip fabrication method as claimed in claim 1, wherein said plastic substrate has a thickness smaller than 0.5 mm.

5. The plastic code wheel/code strip fabrication method as claimed in claim 1, wherein the chrome-aluminum film deposited on the surface of said plastic substrate during step b) has a thickness below 1 μm.

6. The plastic code wheel/code strip fabrication method as claimed in claim 1, wherein the photoresist layer formed on said chrome-aluminum film during step c) has a thickness of 1˜3 μm.

7. The plastic code wheel/code strip fabrication method as claimed in claim 1, wherein the cleaning solution applied during step g) and step i) is an alkaline solution.

8. The plastic code wheel/code strip fabrication method as claimed in claim 1, wherein the etching solution applied during step h) is a nitride acid solution.

9. The plastic code wheel/code strip fabrication method as claimed in claim 1, wherein the dip-etching in step h) is performed for a duration of no longer than one minute.
